(19) United States
(12) Patent Application Publication
(10) Pub. No.: US 2021/0082712 A1
(43) Pub. Date: Mar. 18, 2021

(54) METHOD OF ETCHING SILICON OXIDE FILM AND PLASMA PROCESSING APPARATUS

(71) Applicant: Tokyo Electron Limited, Tokyo (JP)

(72) Inventors: Koki CHINO, Kurokawa-gun (JP); Satoshi YAMADA, Kurokawa-gun (JP); Yoshimitsu KON, Kurokawa-gun (JP)

(73) Assignee: Tokyo Electron Limited, Tokyo (JP)

(21) Appl. No.: 17/010,983

(22) Filed: Sep. 3, 2020

(30) Foreign Application Priority Data
Sep. 17, 2019 (JP) 2019-168083

(51) Int. Cl. H01L 21/311; H01L 21/67; H01J 37/32

(52) U.S. Cl. CPC H01L 21/31116; H01L 21/31144; H01L 21/67069; H01J 2237/334; H01J 37/32082; H01J 37/32724; H01J 37/32449

(57) ABSTRACT

A disclosed method etches a silicon oxide film of a substrate on which a mask is provided. The method includes performing first plasma processing on a substrate by using a first plasma formed from a first processing gas including a fluorocarbon gas, a fluorine-free carbon-containing gas, and an oxygen-containing gas. The method further includes performing second plasma processing on the substrate by using a second plasma formed from a second processing gas including a fluorocarbon gas. A temperature of the substrate during the first plasma processing is lower than the temperature of the substrate during the second plasma processing.

### CROSS-REFERENCE TO RELATED APPLICATIONS

This application is based on and claims the benefit of priority from Japanese Patent Application No. 2019-168083 filed on Sep. 17, 2019, the entire contents of which are incorporated herein by reference.

### FIELD

Exemplary embodiments of the present disclosure relate to a method of etching a silicon oxide film and a plasma processing apparatus.

### BACKGROUND

Plasma etching of a silicon oxide film is used to transfer a pattern of a mask to the silicon oxide film. Japanese Patent Application Laid-Open Publication No. 2011-204999 (hereinafter referred to as “Patent Document 1”) discloses plasma etching of a silicon oxide film. In the plasma etching described in Patent Document 1, the silicon oxide film is etched by using plasma formed from a fluorocarbon gas.

### SUMMARY

In an exemplary embodiment, a method of etching a silicon oxide film of a substrate is provided. The substrate has the silicon oxide film and a mask. The mask is provided on the silicon oxide film. The method includes (a) performing first plasma processing on the substrate by using a first plasma formed from a first processing gas. The first processing gas includes a fluorocarbon gas, a fluorine-free carbon-containing gas, and an oxygen-containing gas. A temperature of the substrate is set to a first temperature during the first plasma processing. A carbon-containing substance is deposited on the mask and the silicon oxide film is etched by the first plasma processing. The method further includes (b) performing second plasma processing on the substrate by using a second plasma formed from a second processing gas including a fluorocarbon gas, after the operation (a). The temperature of the substrate is set to a second temperature during the second plasma processing. The silicon oxide film is etched by the second plasma processing. The first temperature is lower than the second temperature.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a flow chart of a method of etching a silicon oxide film according to one exemplary embodiment.

FIG. 2 is a partially enlarged cross-sectional view of an exemplary substrate.

FIG. 3 is a partially enlarged cross-sectional view of an exemplary substrate.

FIG. 4 is a diagram schematically showing a plasma processing apparatus according to an exemplary embodiment.

FIG. 5A is a partially enlarged cross-sectional view of the exemplary substrate in a state after performing a step STa of the method shown in FIG. 1, and FIG. 5B is a partially enlarged cross-sectional view of an exemplary substrate in a state after performing a step STb of the method shown in FIG. 1.

FIG. 6 is a partially enlarged cross-sectional view of the exemplary substrate in a state after performing a step STc of the method shown in FIG. 1.

FIG. 7A is a partially enlarged cross-sectional view of the exemplary substrate in a state after performing a step ST1 of the method shown in FIG. 1, and FIG. 7B is a partially enlarged cross-sectional view of an exemplary substrate in a state after performing a step ST2 of the method shown in FIG. 1.

### DETAILED DESCRIPTION

Hereinafter, various exemplary embodiments will be described.

In an exemplary embodiment, a method of etching a silicon oxide film of a substrate is provided. The substrate has the silicon oxide film and a mask. The mask is provided on the silicon oxide film. The method includes (a) performing first plasma processing on the substrate by using a first plasma formed from a first processing gas. The first processing gas includes a fluorocarbon gas, a fluorine-free carbon-containing gas, and an oxygen-containing gas. A temperature of the substrate is set to a first temperature during the first plasma processing. A carbon-containing substance is deposited on the mask and the silicon oxide film is etched by the first plasma processing. The method further includes (b) performing second plasma processing on the substrate by using a second plasma formed from a second processing gas including a fluorocarbon gas, after the operation (a). The temperature of the substrate is set to a second temperature during the second plasma processing. The silicon oxide film is etched by the second plasma processing. The first temperature is lower than the second temperature.

In a case where the temperature of the substrate is set to a relatively low temperature, a relatively large amount of carbon-containing material is deposited on the surface of the substrate from the plasma. Therefore, as a result of the first plasma processing, a relatively large amount of carbon-containing material is deposited on the mask. In addition, the silicon oxide film is etched by the fluorine species from the first plasma during the first plasma processing. While performing the second plasma processing, the silicon oxide film is further etched by the fluorine species from the second plasma. On the other hand, the mask is protected while performing the second plasma processing by the carbon-containing material deposited on the mask as a result of the first plasma processing. Hence, according to the method according to the above-described embodiment, it is possible to suppress the decrease in film thickness of the mask due to the etching of the silicon oxide film.

In an exemplary embodiment, the first processing gas and the second processing gas may be the same processing gas.

In an exemplary embodiment, the operation (a) and the operation (b) may be performed by using a plasma processing apparatus. A radio frequency power used to generate the first plasma in the plasma processing apparatus in the operation (a) may be lower than a radio frequency power used to generate the second plasma in the plasma processing apparatus in the operation (b). In a case where a small radio frequency power is used, the density of the plasma becomes low and the amount of heat given to the substrate from the plasma becomes small. According to the embodiment, the temperature of the substrate W is set to the first temperature while performing the first plasma processing and is set to the second temperature while performing the second plasma processing.

In an exemplary embodiment, an amount of electric power of a heater in a substrate support that supports the substrate may be adjusted such that the first temperature is lower than the second temperature, in the operation (a) and the operation (b).

In an exemplary embodiment, in the first processing gas, the fluorine-free carbon-containing gas may be CO gas and the oxygen-containing gas may be O₂ gas.

In an exemplary embodiment, the mask may be a mask formed of an organic material.

In another exemplary embodiment, a plasma processing apparatus is provided. The plasma processing apparatus includes a chamber, a substrate support, a gas supply unit, a radio frequency power supply and a controller. The substrate support is provided in the chamber. The gas supply unit is configured to supply a first processing gas and a second processing gas into the chamber. The first processing gas includes a fluorocarbon gas, a fluorine-free carbon-containing gas, and an oxygen-containing gas. The second processing gas includes a fluorocarbon gas. The radio frequency power supply is configured to generate radio frequency power for generating plasma from gas in the chamber. The controller is configured to control the gas supply unit and the radio frequency power supply. The controller performs first control to control the gas supply unit to supply the first processing gas into the chamber and control the radio frequency power supply to generate a first plasma from the first processing gas in the chamber. The first control is performed to etch a silicon oxide film of a substrate and to form a carbon-containing deposit on a mask of the substrate provided on the silicon oxide film. The controller performs second control to control the gas supply unit to supply the second processing gas into the chamber and control the radio frequency power supply to generate a second plasma from the second processing gas in the chamber, to further etch the silicon oxide film. The controller sets a temperature of the substrate in the first control to a temperature lower than a temperature of the substrate which is set in the second control.

Hereinafter, various exemplary embodiments will be described in detail with reference to the drawings. In the drawing, the same or equivalent portions are denoted by the same reference symbols.

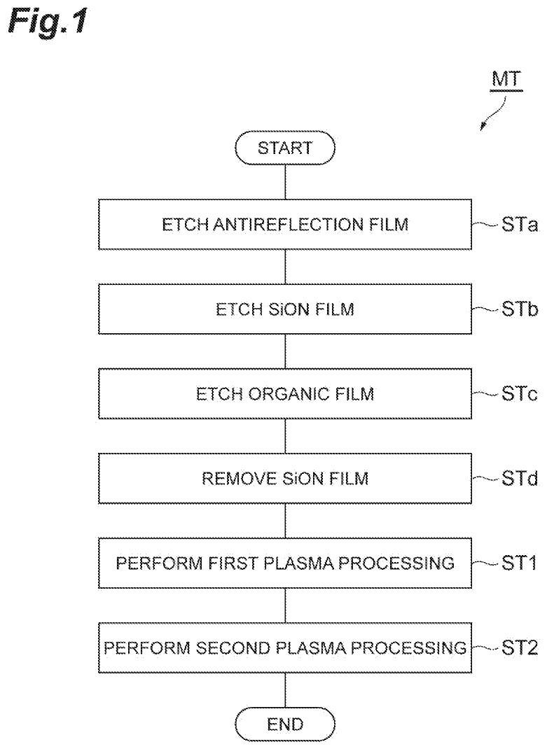

FIG. 1 is a flow chart of a method of etching a silicon oxide film according to one exemplary embodiment. The method shown in FIG. 1 (hereinafter referred to as “method MT”) is performed to etch the silicon oxide film on the substrate. The method MT includes a step ST1 and a step ST2.

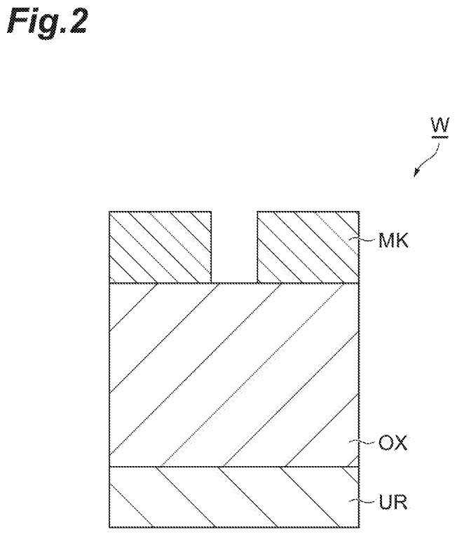

FIG. 2 is a partially enlarged cross-sectional view of an exemplary substrate. The steps ST1 and ST2 of the method MT can be applied to the substrate W shown in FIG. 2. The substrate W shown in FIG. 2 has a silicon oxide film OX and a mask MK. The substrate W may further have an underlying region UR. The silicon oxide film OX may be provided on the underlying region UR. The mask MK is provided on the silicon oxide film OX. The mask MK has a pattern transferred to the silicon oxide film OX by etching. That is, the mask MK provides an opening that partially exposes the surface of the silicon oxide film. The mask MK is made of, for example, an organic material. However, the mask MK may be formed of any material as long as the etching rate of the silicon oxide film OX is higher than the etching rate of the mask MK.

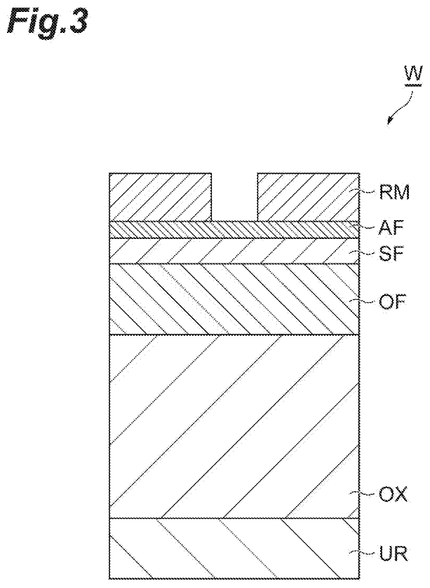

FIG. 3 is a partially enlarged cross-sectional view of an exemplary substrate. In an embodiment, the substrate W may have a configuration shown in FIG. 3 before the steps ST1 and ST2 are applied thereto. The substrate W shown in FIG. 3 further has an organic film OF, a SiON film SF, an antireflection film AF, and a resist mask RM. The organic film OF is provided on the silicon oxide film OX. The organic film OF is formed of an organic material. The organic film OF is, for example, an amorphous carbon film. The SiON film SF is provided on the silicon oxide film OX. The antireflection film AF is made of an organic material and is provided on the silicon oxide film OX. The resist mask RM is a photoresist mask and is provided on the antireflection film AF. The resist mask RM has a pattern for forming the mask MK from the organic film OF. The resist mask RM is patterned by using, for example, the photolithography technique. The method MT may further include steps STa to STd to obtain the substrate W in the state shown in FIG. 2 from the substrate W in the state shown in FIG. 3.

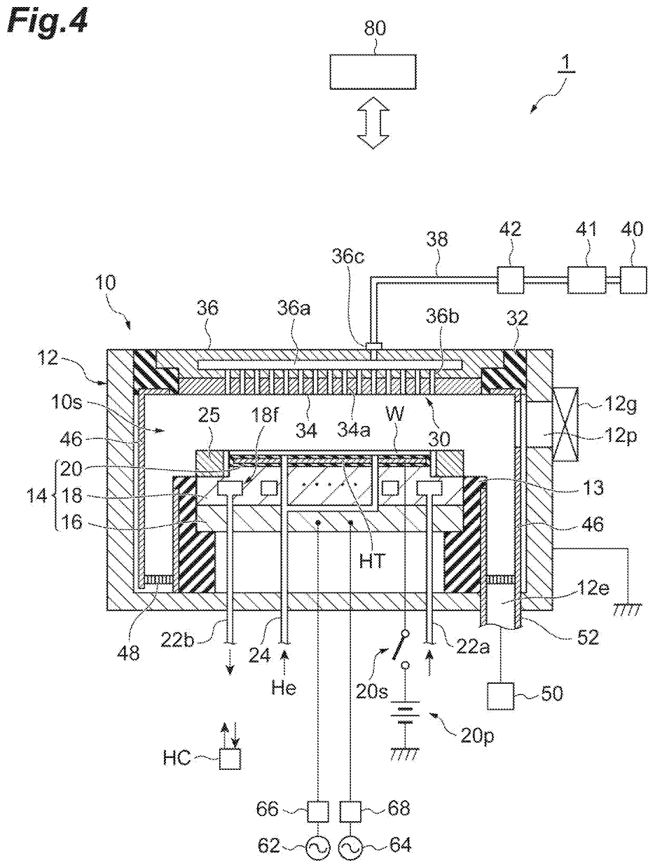

In an embodiment, the method MT is performed using a plasma processing apparatus. FIG. 4 is a diagram schematically showing a plasma processing apparatus according to an exemplary embodiment. The plasma processing apparatus 1 shown in FIG. 4 includes a chamber 10. The chamber 10 provides an internal space 10s therein. The chamber 10 includes a chamber body 12. The chamber body 12 has substantially cylindrical shape. The chamber body 12 is made of, for example, aluminum. A film having corrosion resistance is formed on an inner wall surface of the chamber body 12. The film may be ceramics such as aluminum oxide or yttrium oxide.

A passageway 12p is formed in a sidewall of the chamber body 12. The substrate W is transferred between the internal space 10s and the outside of the chamber 10 through the passageway 12p. The passageway 12p is opened or closed by a gate valve 12g. The gate valve 12g is provided along the sidewall of the chamber body 12.

A support 13 is provided on a bottom portion of the chamber body 12. The support 13 is made of an insulating material. The support 13 has a substantially cylindrical shape. The support 13 extends upward in the internal space 10s from the bottom portion of the chamber body 12. The support 13 supports a substrate support 14. The substrate support 14 is provided in the chamber 10. The substrate support 14 is configured to support the substrate W in the internal space 10s.

The substrate support 14 has a lower electrode 18 and an electrostatic chuck 20. The substrate support 14 may further include an electrode plate 16. The electrode plate 16 is made of a conductor such as aluminum and has a substantially disk shape. The lower electrode 18 is provided on the electrode plate 16. The lower electrode 18 is made of a conductor such as aluminum and has a substantially disk shape. The lower electrode 18 is electrically connected to the electrode plate 16.

The electrostatic chuck 20 is provided on the lower electrode 18. The substrate W is placed on an upper surface of the electrostatic chuck 20. The electrostatic chuck 20 has a main body and an electrode. The main body of the electrostatic chuck 20 has a substantially disk shape and is made of a dielectric material. The electrode of the electrostatic chuck 20 is an electrode in the form of a film and provided in the main body of the electrostatic chuck 20. The electrode of the electrostatic chuck 20 is connected to a direct current power source 20p through a switch 20s. Electrostatic attractive force is generated between the electrostatic chuck 20 and the substrate W when a voltage is applied to the electrode of the electrostatic chuck 20 from the direct current power source 20p. The substrate W is held by the electrostatic chuck 20 by the electrostatic attractive force.

An edge ring 25 is disposed on a circumferential edge portion of the substrate support 14 to surround an edge of the substrate W. The edge ring 25 may improve in-plane uniformity of the plasma processing performed on the substrate W. The edge ring 25 may be made of for example, silicon, silicon carbide, or quartz.

A flow path 18f is provided in the lower electrode 18. A heat exchange medium (e.g., coolant) is supplied into the flow path 18f through a pipe 22a from a chiller unit 22 (not shown) provided outside the chamber 10. The heat exchange medium supplied into the flow path 18f returns back to the chiller unit through the pipe 22b. In the plasma processing apparatus 1, a temperature of the substrate W placed on the electrostatic chuck 20 is adjusted by heat exchange between the heat exchange medium and the lower electrode 18.

In an embodiment, the substrate support 14 may further have a heater HT. The heater HT is provided in the substrate support 14 to heat the substrate W. The heater HT may be provided in the electrostatic chuck 20. Electric power is supplied from a heater controller HC to the heater HT. The heater controller HC is configured to adjust an amount of electric power of the heater HT.

In the plasma processing apparatus 1, a gas supply line 24 is provided. The gas supply line 24 supplies heat transfer gas (e.g., He gas) from a heat transfer gas supply mechanism to a portion between an upper surface of the electrostatic chuck 20 and a rear surface of the substrate W.

The plasma processing apparatus 1 further includes an upper electrode 30. The upper electrode 30 is provided above the substrate support 14. The upper electrode 30 is supported at an upper portion of the chamber body 12 via a member 32. The member 32 is made of an insulating material. The upper electrode 30 and the member 32 close an upper opening of the chamber body 12.

The upper electrode 30 may include a ceiling plate 34 and a support 36. A lower surface of the ceiling plate 34, which is a lower surface directed toward the internal space 10s, defines the internal space 10s. The ceiling plate 34 may be made of a semiconductor material or a low-resistance conductor, in which low Joule heat is generated. The ceiling plate 34 has a plurality of gas discharge holes 34a that penetrate in a direction of a plate thickness of the ceiling plate 34.

The support body 36 detachably supports the ceiling plate 34. The support body 36 is made of a conductive material such as aluminum. A gas diffusion space 36a is provided in the support body 36. The support body 36 has a plurality of gas holes 36b that extend downward from the gas diffusion space 36a. The gas holes 36b are in communication with the gas discharge holes 34a respectively. A gas introduction port 36c is formed in the support body 36. The gas introduction port 36c is connected to the gas diffusion space 36a. A gas supply pipe 38 is connected to the gas introduction port 36c.

A gas source group 40 is connected to the gas supply pipe 38 through a flow rate controller group 41 and a valve group 42. The gas source group 40 includes a plurality of gas sources. The flow rate controller group 41 includes a plurality of flow rate controllers. Each of the flow rate controllers of the flow rate controller group 41 is a mass flow controller or a pressure-control flow rate controller. The valve group 42 includes a plurality of on-off valves. Each of the gas sources of the gas source group 40 is connected to the gas supply pipe 38 through a corresponding flow rate controller of the flow rate controller group 41 and a corresponding on-off valve of the valve group 42. The gas source group 40, the flow rate controller group 41, and the valve group 42 constitute a gas supply unit. The gas supply unit is configured to supply a first processing gas and a second processing gas, which will be described later, into the chamber 10

In the plasma processing apparatus 1, a shield 46 is detachably provided along the inner wall surface of the chamber body 12 and an outer circumference of the support 13. The shield 46 prevents reactive by-product from being attached to the chamber body 12. The shield 46 is formed by forming a corrosion-resistant film on a surface of a base member made of, for example, aluminum. The corrosion-resistant film may be ceramics such as yttrium oxide.

A baffle plate 48 is provided between the support 13 and the sidewall of the chamber body 12. The baffle plate 48 is formed by forming a corrosion-resistant film (e.g. a film such as yttrium oxide film) on a surface of a base member such as aluminum. The baffle plate 48 has a plurality of through holes. A gas discharge port 12e is provided below the baffle plate 48 and in the bottom portion of the chamber body 12. An exhaust device 50 is connected to the gas discharge port 12e through a gas discharge pipe 52. The exhaust device 50 includes a pressure control valve and a vacuum pump such as a turbo molecular pump.

The plasma processing apparatus 1 includes a first radio-frequency power source 62 and a second radio frequency power source 64. The first radio frequency power source 62 is a power source that generates first radio frequency power. The first radio frequency electric power has a frequency suitable for generating plasma. The frequency of the first radio frequency power is, for example, a frequency within a range of 27 MHz to 100 MHz. The first radio frequency power source 62 is connected to the lower electrode 18 through a matcher 66 and the electrode plate 16. The matcher 66 has a circuit for matching impedance at a load side (lower electrode 18 side) of the first radio frequency power source 62 with output impedance of the first radio frequency power source 62. In another example, the first radio frequency power source 62 may be connected to the upper electrode 30 through the matcher 66. The first radio frequency power source 62 constitutes an example of a plasma producing unit.

The second radio frequency power source 64 is a power source that generates second radio frequency electric power. The second radio frequency electric power has a frequency lower than the frequency of the first radio frequency electric power. When the second radio frequency electric power is used together with the first radio frequency electric power, the second radio frequency electric power is used as bias radio frequency electric power for attracting ions to the substrate W. The frequency of the second radio frequency electric power is, for example, a frequency within a range of 400 kHz to 13.56 MHz. The second radio frequency power source 64 is connected to the lower electrode 18 through a matcher 68 and the electrode plate 16. The matcher 68 has a circuit for matching impedance at a load side (lower electrode 18 side) of the second radio frequency power source 64 with output impedance of the second radio frequency power source 64.

The plasma may be produced by using the second radio frequency electric power without using the first radio frequency electric power, that is, by using only single radio frequency electric power. In such a case, the frequency of the second radio frequency electric power may be a frequency higher than 13.56 MHz, for example, a frequency of 40 MHz. In such a case, the plasma processing apparatus 1 may have neither the first radio frequency power source 62 nor the matching device 66. In such a case, the second radio frequency power source 64 constitutes an example of the plasma producing unit.

In the plasma processing apparatus 1, gas is supplied into the internal space 10s from the gas supply unit to produce the plasma. In addition, the first radio frequency electric power and/or the second radio frequency electric power is supplied to produce a radio frequency electric field between the upper electrode 30 and the lower electrode 18 as. The produced radio frequency electric field produces plasma.

The plasma processing apparatus 1 may further include a controller 80. The controller 80 may be a computer including, for example, a processor, a storage unit such as a memory, an input device, a display device, and a signal input-output interface. The controller 80 controls respective parts of the plasma processing apparatus 1. The controller 80 may allow an operator to perform an operation of inputting a command to manage the plasma processing apparatus 1 by using the input device. In addition, the controller 80 may visibly display an operational situation of the plasma processing apparatus 1 through the display device. Further, the storage unit stores a control program and recipe data. The control program is executed by the processor to perform various types of processing in the plasma processing apparatus 1. The processor executes the control program and controls the respective parts of the plasma processing apparatus 1 in accordance with the recipe data.

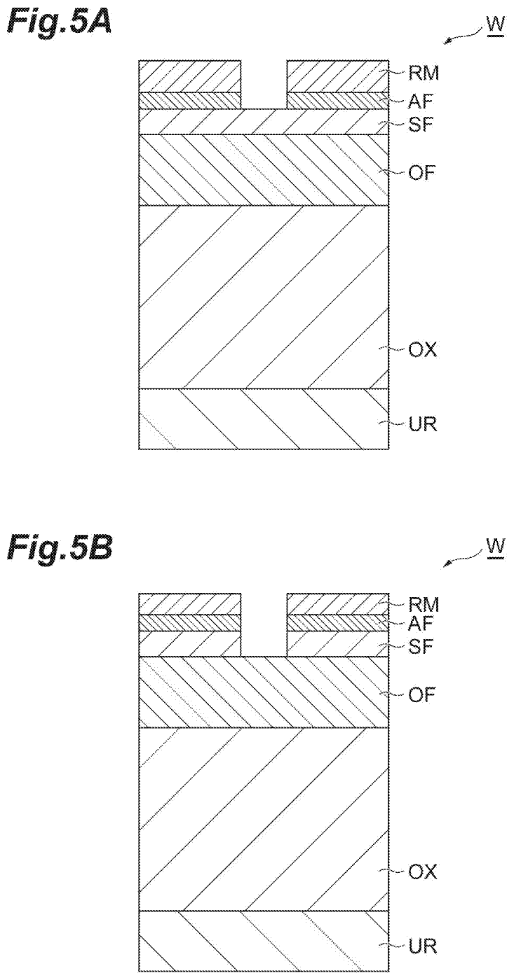

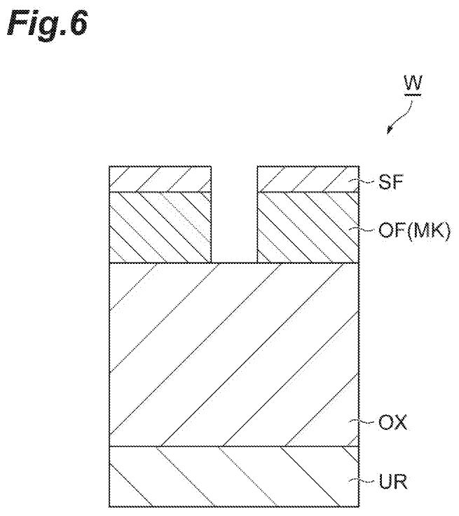

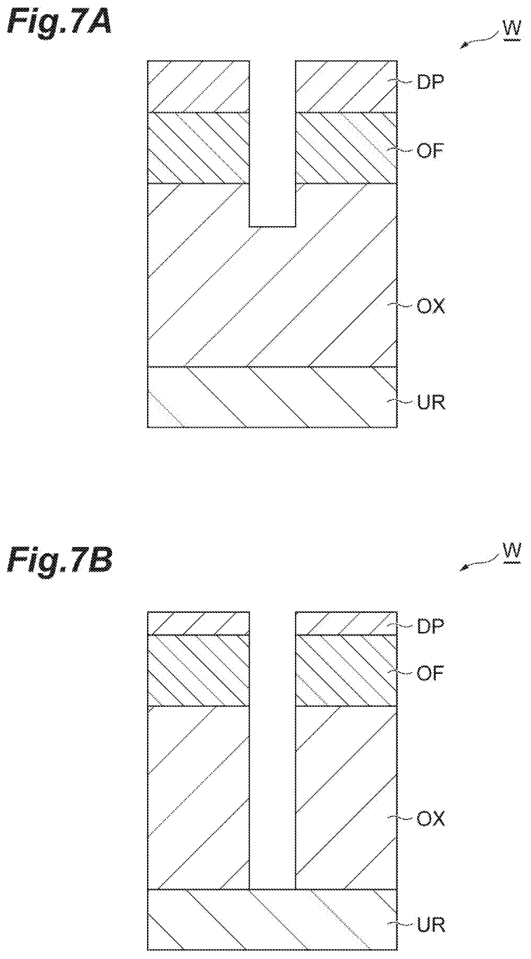

Hereinafter, the method MT will be described in detail with reference to FIG. 1 again. Hereinafter, the method MT will be described by taking as an example the case where the steps STa to STd, the step ST1, and the step ST2 are applied to the substrate W shown in FIG. 3. Further, in the following description, FIG. 5A, FIG. 5B, FIG. 6, FIG. 7A, and FIG. 7B are also referred to. FIG. 5A, FIG. 5B, FIG. 6, FIG. 7A, and FIG. 7B are respectively partially enlarged cross-sectional views of exemplary substrates in a state after performing the step STa, the step STb, the step STc, the step ST1, and the step ST2 of the method shown in FIG. 1.

In the step STa, the antireflection film is etched by plasma etching in order to transfer the pattern of the resist mask RM to the antireflection film AF. In the step STa, plasma is generated from a processing gas in the chamber 10. The processing gas used in the step STa may include an oxygen-containing gas (for example, oxygen gas). Alternatively, the processing gas used in the step STa may include a nitrogen gas and a hydrogen gas. In the step STa, the antireflection film AF is etched by the chemical species from the generated plasma. As a result, as shown in FIG. 5A, the pattern of the resist mask RM is transferred to the antireflection film AF.

In order to perform the step STa, the controller 80 controls the gas supply unit to supply the processing gas into the chamber 10. In order to perform the step STa, the controller 80 controls the exhaust device 50 to set the pressure inside the chamber 10 to the designated pressure. In order to perform the step STa, the controller 80 controls the first radio frequency power supply 62 and/or the second radio frequency power supply 64 to supply the first radio frequency power and/or the second radio frequency power.

In the subsequent step STb, the SiON film SF is etched by plasma etching in order to transfer the pattern of the antireflection film AF to the SiON film SF. In the step STb, plasma is generated from a processing gas in the chamber 10. The processing gas used in the step STb includes a hydrofluorocarbon gas. The processing gas used in the step STb may further include a fluorocarbon gas. The processing gas used in the step STb may further include other gas such as an oxygen gas and/or a rare gas. In the step STb, the SiON film SF is etched by the chemical species from the generated plasma. As a result, as shown in FIG. 5B, the pattern of the antireflection film AF is transferred to the SiON film SF.

In order to perform the step STb, the controller 80 controls the gas supply unit to supply the processing gas into the chamber 10. In order to perform the step STb, the controller 80 controls the exhaust device 50 to set the pressure inside the chamber 10 to the designated pressure. In order to perform the step STb, the controller 80 controls the first radio frequency power supply 62 and/or the second radio frequency power supply 64 to supply the first radio frequency power and/or the second radio frequency power.

In the subsequent step STc, the organic film OF is etched by plasma etching in order to transfer the pattern of the SiON film SF to the organic film OF. In the step STc, plasma is generated from a processing gas in the chamber 10. The processing gas used in the step STc may include an oxygen-containing gas (for example, oxygen gas). Alternatively, the processing gas used in the step STc may include nitrogen gas and hydrogen gas. In the step STc, the organic film OF is etched by the chemical species from the generated plasma. As a result, as shown in FIG. 6, the pattern of the SiON film SF is transferred to the organic film OF, and the mask MK is formed from the organic film OF. While performing the step STc, the resist mask RM and the antireflection film AF are removed by the chemical species from the plasma.

In order to perform the step STc, the controller 80 controls the gas supply unit to supply the processing gas into the chamber 10. In order to perform the step STc, the controller 80 controls the exhaust device 50 to set the pressure inside the chamber 10 to the designated pressure. In order to perform the step STc, the controller 80 controls the first radio frequency power supply 62 and/or the second radio frequency power supply 64 to supply the first radio frequency power and/or the second radio frequency power.

In the subsequent step STd, the SiON film SF is removed. In the step STd, plasma is generated from a processing gas in the chamber 10. The processing gas used in the step STd includes a hydrofluorocarbon gas. The processing gas used in the step STd may further include a fluorocarbon gas. The processing gas used in the step STd may further include other gas such as an oxygen gas and/or a rare gas. In the step STd, the SiON film SF is etched and removed by the chemical species from the generated plasma. As a result, the substrate W shown in FIG. 2 is obtained.

In order to perform the step STd, the controller 80 controls the gas supply unit to supply the processing gas into the chamber 10. In order to perform the step STd, the controller 80 controls the exhaust device 50 to set the pressure inside the chamber 10 to the designated pressure. In order to perform the step STd, the controller 80 controls the first radio frequency power supply 62 and/or the second radio frequency power supply 64 to supply the first radio frequency power and/or the second radio frequency power.

In the subsequent step ST1, the first plasma processing is performed. That is, in the step ST1, the substrate W is processed using the first plasma formed from the first processing gas. The first processing gas includes a fluorocarbon gas, a fluorine-free carbon-containing gas, and an oxygen-containing gas. The fluorocarbon gas in the first processing gas is a gas composed of any molecule represented by C_{X}F_{Y}. The fluorocarbon gas is, for example, C₄F₆ gas. In the first processing gas, the fluorine-free carbon-containing gas is, for example, CO gas or CO₂ gas. The oxygen-containing gas in the first processing gas is an oxygen gas, for example. In the step ST1, plasma is generated from the first processing gas in the chamber 10.

In the step ST1, the temperature of the substrate W is set to the first temperature. The first temperature is lower than the second temperature which is the temperature of the substrate W in the step ST2. The first temperature is, for example, a temperature lower than 50° C. In an embodiment, in order to set the temperature of the substrate W to the first temperature in the step ST1, the first radio frequency power is set to be lower than the first radio frequency power used in the step ST2. In a case where a small radio frequency power is used, the density of the plasma becomes low and the amount of heat given to the substrate W from the plasma becomes small. According to the embodiment, the temperature of the substrate W is set to the first temperature while performing the first plasma processing by adjusting at least the radio frequency power.

In another embodiment, the temperature of the substrate W during the first plasma processing may be set to the first temperature by adjusting the amount of electric power of the heater HT. Further, in another embodiment, the temperature of the substrate W in the step ST1 may be set to the first temperature through both the adjustment of the first radio frequency power and the adjustment of the amount of electric power of the heater HT.

In a case where the temperature of the substrate W is set to a relatively low temperature, a relatively large amount of carbon-containing material is deposited on the surface of the substrate W from the first plasma. Therefore, as a result of the first plasma processing, a relatively large amount of the carbon-containing material DP is deposited on the mask MK, as shown in FIG. 7A. Further, while performing the first plasma processing, the silicon oxide film OX is etched by the fluorine species from the first plasma.

In order to perform the step ST1, the controller 80 controls the gas supply unit to supply the first processing gas into the chamber 10. In order to perform the step ST1, the controller 80 controls the exhaust device 50 to set the pressure inside the chamber 10 to the designated pressure. In order to perform the step ST1, the controller 80 controls the first radio frequency power supply 62 and the second radio frequency power supply 64 to supply the first radio frequency power and the second radio frequency power. In the step ST1, one of the first radio frequency power and the second radio frequency power may not be supplied. Moreover, in order to set the temperature of the substrate W to the first temperature in the step ST1, the controller 80 controls the first radio frequency power supply 62 and/or the heater controller HC.

The step ST2 is performed after the step ST1. In the step ST2, the second plasma processing is performed. That is, in the step ST2, the substrate W is processed using the second plasma formed from the second processing gas. The second processing gas is a gas including a fluorocarbon gas. In an embodiment, the second processing gas may be the same gas as the first processing gas. That is, the second processing gas may include a fluorocarbon gas, a fluorine-free carbon-containing gas, and an oxygen-containing gas. The fluorocarbon gas in the second processing gas is a gas composed of any molecule represented by C_{X}F_{Y}. The fluorocarbon gas is, for example, C₄F₆ gas. In the second processing gas, the fluorine-free carbon-containing gas is, for example, CO gas or CO₂ gas. The oxygen-containing gas in the second processing gas is an oxygen gas, for example. In the step ST2, plasma is generated in the chamber 10 from the second processing gas.

In the step ST2, the temperature of the substrate W is set to the second temperature. The second temperature is higher than the first temperature which is the temperature of the substrate W in the step ST1. The second temperature is, for example, a temperature equal to or higher than 50° C. In an embodiment, in order to set the temperature of the substrate W to the second temperature in the step ST2, the first radio frequency power is set to be higher than the first radio frequency power used in the step ST.

In another embodiment, the temperature of the substrate W during the second plasma processing may be set to the second temperature by adjusting the amount of electric power of the heater HT. Further, in another embodiment, the temperature of the substrate W in the step ST2 may be set to the second temperature through both the adjustment of the first radio frequency power and the adjustment of the amount of electric power of the heater HT.

While performing the second plasma processing, the silicon oxide film OX is further etched by the fluorine species from the second plasma. On the other hand, the mask MK is protected while performing the second plasma processing by the carbon-containing material DP deposited on the mask MK as a result of the first plasma processing (refer to FIG. 7B). Hence, according to the method MT, it is possible to suppress the decrease in film thickness of the mask MK due to the etching of the silicon oxide film OX.

In order to perform the step ST2, the controller 80 controls the gas supply unit to supply the second processing gas into the chamber 10. In order to perform the step ST2, the controller 80 controls the exhaust device 50 to set the pressure inside the chamber 10 to the designated pressure. In order to performed the step ST2, the controller 80 controls the first radio frequency power supply 62 and the second radio frequency power supply 64 to supply the first radio frequency power and the second radio frequency power. Moreover, in order to set the temperature of the substrate W to the second temperature in the step ST2, the controller 80 controls the first radio frequency power supply 62 and/or the heater controller HC.

While various exemplary embodiments have been described above, various additions, omissions, substitutions and changes may be made without being limited to the exemplary embodiments described above. Elements of the different embodiments may be combined to form another embodiment.

For example, at least one of the step STa, the step STb, the step STc, the step STd, the step ST1, or the step ST2 of the method IT may be performed using a plasma processing apparatus different from the plasma processing apparatus used in other steps of the method MT.

Further, a capacitively coupled plasma processing apparatus different from the plasma processing apparatus 1 or a different type of plasma processing apparatus may be used to performed the method MT. Examples of the different type of plasma processing apparatus include a capacitively coupled plasma processing apparatus and a plasma processing apparatus that excites gas by using surface waves such as microwaves.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of etching a silicon oxide film of a substrate having the silicon oxide film and a mask provided on the silicon oxide film, the method comprising:
(a) performing first plasma processing on the substrate by using a first plasma formed from a first processing gas including a fluorocarbon gas, a fluorine-free carbon-containing gas, and an oxygen-containing gas, wherein a temperature of the substrate is set to a first temperature during the first plasma processing, and a carbon-containing substance is deposited on the mask and the silicon oxide film is etched by the first plasma processing; and
(b) performing second plasma processing on the substrate by using a second plasma formed from a second processing gas including a fluorocarbon gas after (a), wherein the temperature of the substrate is set to a second temperature during the second plasma processing, and the silicon oxide film is etched by the second plasma processing,
wherein the first temperature is lower than the second temperature.

2. The method according to claim 1, wherein the first processing gas and the second processing gas are the same processing gas.

3. The method according to claim 1,
wherein (a) and (b) are performed by using a plasma processing apparatus, and
wherein a radio frequency power used to generate the first plasma in the plasma processing apparatus in (a) is lower than a radio frequency power used to generate the second plasma in the plasma processing apparatus in (b).

4. The method according to claim 1, wherein in (a) and (b), an amount of electric power of a heater in a substrate support that supports the substrate is adjusted such that the first temperature is lower than the second temperature.

5. The method according to claim 1, wherein the fluorine-free carbon-containing gas is CO gas, and the oxygen-containing gas is 02 gas.

6. The method according to claim 1, wherein the mask is a mask formed of an organic material.

7. A plasma processing apparatus comprising:
a chamber;
a substrate support provided in the chamber;
a gas supply unit configured to supply a first processing gas including a fluorocarbon gas, a fluorine-free carbon-containing gas, and an oxygen-containing gas, and a second processing gas including a fluorocarbon gas, into the chamber;
a radio frequency power supply configured to generate radio frequency power for generating plasma from gas in the chamber; and
a controller configured to control the gas supply unit and the radio frequency power supply,
wherein the controller
performs first control to control the gas supply unit to supply the first processing gas into the chamber and control the radio frequency power supply to generate a first plasma from the first processing gas in the chamber, to etch a silicon oxide film of a substrate and to form a carbon-containing deposit on a mask of the substrate provided on the silicon oxide film,
performs second control to control the gas supply unit to supply the second processing gas into the chamber and control the radio frequency power supply to generate a second plasma from the second processing gas in the chamber, to further etch the silicon oxide film, and
sets a temperature of the substrate in the first control to a temperature lower than a temperature of the substrate which is set in the second control.
